(19) United States
(12) Patent Application Publication
(10) Pub. No.: US 2013/0116947 A1
(43) Pub. Date: May 9, 2013

(54) Method and System for Detecting Unbalance in Power Grids

(71) Applicants: Zafer Sahinoglu, Cambridge, MA (US); Sefa Demirtas, Brighton, MA (US)

(72) Inventors: Zafer Sahinoglu, Cambridge, MA (US); Sefa Demirtas, Brighton, MA (US)

(21) Appl. No.: 13/292,201

(22) Filed: Nov. 9, 2011

(51) Int. Cl. G06F 19/00; G01R 31/00; G01R 25/00

(52) U.S. Cl. 702/58; 324/86; 702/60

(57) ABSTRACT

A method for detecting unbalance in a 3-phase voltage signal is disclosed. The method includes determining an unbalance indicator as a value of a square of an amplitude of a positive sequence of the voltage signal; and comparing the unbalance indicator with a threshold to determine unbalance of the voltage signal.

### FIELD OF THE INVENTION

This invention relates generally to electricity power grids, and in particular to detecting unbalance in a 3-phase voltage signal in the power grids.

### BACKGROUND OF THE INVENTION

Synchronization in a utility power grid is important to control the operation of the grid when distributed power generators are connected to the grid. The synchronization includes determining a phase angle of 3-phase voltage signals in the grid. Usually, the grid voltage signal deviates from the ideal condition and is distorted due to, e.g., additive noise, frequency variation, voltage unbalance, and harmonic components. Therefore, the unbalance impacts accurate synchronization. In presence of the unbalance, the three-phase voltage signal can be decomposed into positive, negative and zero sequences.

The unbalance of the signal may take place in amplitude, initial phase of the signal, or both. Detection of the unbalance is a challenging problem especially for the phase unbalance, which cannot be detected by measuring and comparing the amplitudes of the three voltage phases. A detector with good performance for both amplitude and phase unbalance has yet to be developed.

Unbalance detection is an indicator of islanding. Islanding is a condition in which a distributed generation (DG) generator continues to power a location even though electrical grid power from the electric utility is no longer present. During islanding, DGs should be immediately disconnected from the grid.

The unbalance of the voltage signal can be conventionally detected by monitoring several parameters of the signal, such as voltage magnitude, phase displacement, and frequency change. However, those conventional methods may fail to detect small variation of signal. For example, one method uses the ratio of the magnitude of negative sequence voltage to the magnitude of the positive voltage sequence, VU=|Vₙ|/|Vₚ|. However, that ratio is a weak indicator. The magnitude of the negative sequence voltage |Vₙ| is typically much less than the magnitude of the positive sequence. Thus, the positive sequence suppresses the ratio VU.

The ratio is not suitable to detect small unbalance conditions. If the threshold for permissible disturbance in these quantities is set to a low value, then nuisance tripping becomes an issue. If the threshold is set too high, islanding may not be detected. Prior art techniques do not suggest\how to set the threshold. For example, one method sets the threshold statically based on the average value of VU over the past one second, i.e., Tₕ=35VU_{avg}. However, such threshold is inaccurate, and often needs to be updated.

FIG. 1 shows a block diagram of a conventional unbalance detector 100. The detector acquires three phase voltage signals 111 at an input terminal 110. An analog to digital (A/D) converter 130 digitizes the voltage waveforms and produces a discrete signal 135. Then, Clarke's transformation 140 is applied to transform the 3-channel signals 135 onto 2-channels 145 with 90 degree phase difference. Positive and negative sequence voltage waveforms 155 are estimated 150.

Prior art techniques typically use the ratio VU 180 of the negative sequence voltage amplitude to the positive sequence voltage amplitude. The ratio 181 is monitored and compared 191 to a threshold. If the ratio 181 changes as much as the change coefficient 190 times the original value, an unbalance is detected.

For example, one method sets the change coefficient to 35. Such a solution is very static and does not consider whether or how much the estimates are biased, and what the characteristics of the covariance of the estimates are. Therefore, the prior art approaches select heuristic thresholds and are subject to poor performance.

Accordingly there is a need to provide a system and a method for detecting an unbalance in a 3-phase voltage signal.

### SUMMARY OF THE INVENTION

It is an object of present invention to provide a system and a method for detecting an unbalance in a 3-phase voltage signal. It is another object of the invention to detect various degrees of the unbalances. It is further object of the invention to provide an unbalance indicator and a threshold suitable to indicate the unbalance based on the indicator. It is further object of the invention to provide the threshold that is specific for the voltage signal under consideration. It is further object of the invention to detect islanding condition of a power system.

Applicants recognized that there is a need to detect the unbalance of the 3-phase voltage signal based on amplitude of a positive sequence of the voltage signal. This is because the positive sequence of the signal is primarily used in the power system. Applicants further recognized that an estimate of amplitude of positive sequence of the voltage signal is not optimal indicator for detecting the unbalance of the signal, because both a mean and a covariance of the positive sequence are cyclostationary, i.e., dependent of time, which prevents a designer of the unbalance detector from defining an optimal threshold. This is because, for cyclostationary signals, the threshold has to be a function of time.

After extensive searches and experiments, Applicants specifically recognized that the square of amplitude of positive sequence exhibits different statistical properties. Specifically, the covariance of the square of amplitude of positive sequence is still cyclostationary. However, the mean of the square of amplitude of positive sequence is stationary, i.e., independent of time. Accordingly, the threshold selection can be based on that stationary statistical property of the square of amplitude of positive sequence, and can be used during the operation of the power system.

Moreover, the threshold can be a function of the signal-to-noise ratio (SNR) of the voltage signal measured at, e.g., the input terminals of the unbalance detector, and can be used to detect the unbalance at any point of time of operation of the detector based on the square of the positive sequence of the signal. Because the unbalance is indicative of islanding, the islanding condition of a power system can be detected when the unbalance of the power system is detected.

Accordingly, one embodiment of the invention discloses a method for detecting unbalance in a 3-phase voltage signal. The method includes determining an unbalance indicator as a value of a square of amplitude of a positive sequence of the voltage signal; and comparing the unbalance indicator with a threshold to determine unbalance of the voltage signal. Various variation of this embodiment may include one or combination of the following optional features. For example, the threshold can be determined as a function of SNR of the voltage signal. For example, one embodiment determines the threshold according to γ0.606e^{-0.117SNR(dB)}, wherein γ is a guard coefficient greater than one, dB is decibel measure and, e is an exponential.

Another embodiment discloses an unbalance detector, which includes an input terminal for acquiring a 3-phase voltage signal; a threshold computation module for determining a threshold as a function of the SNR of the voltage signal; a processing unit for determining an unbalance indicator as a value of a square of an amplitude of a positive sequence of the voltage signal; a comparison module for comparing the unbalance indicator with the threshold to determine an unbalance of the voltage signal; and an output terminal for signaling the unbalance of the voltage signal.

Various variation of this embodiment may include one or combination of the following optional features. The processing unit can determine the unbalance indicator \hat{V}ₚ² according to

$${\hat{V}}_{p}^{2} = \frac{1}{4} {g}^{T} {C}^{T} Cg ,$$

wherein a matrix C=AB, a matrix B=(H^{T}H)⁻¹H^{T}, a matrix A=[M₁; M₂], a vector M₁=[1 0 0 −1], a vector M₂=[0 −1 −1 0], and T is a transpose operator, and a vector g includes observations of the voltage signal, and a matrix H is a frequency matrix.

Alternatively, the processing unit can determine the unbalance indicator \hat{V}ₚ² according to

$${\hat{V}}_{p}^{2} = \frac{1}{4} {\hat{x}}^{T} {A}^{T} A \hat{x} ,$$

wherein a matrix A=[M₁; M₂], a vector M₁=[1 0 0 −1], a vector M₂=[0 −1 −1 0], \hat{x} is a state vector estimate.

### BRIEF DESCRIPTION OF THE DRAWINGS

FIG. 1 is a block diagram of a prior art unbalance detector;

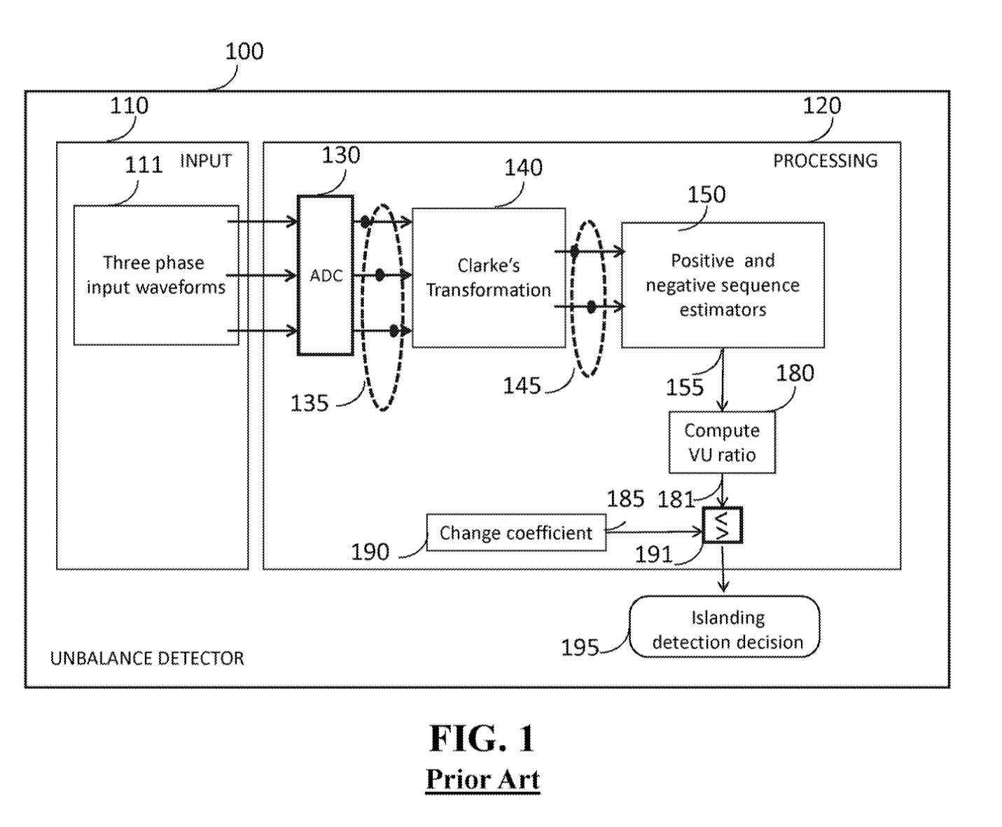

FIG. 2 is a block diagram of a method for detecting unbalance in a 3-phase voltage signal according an embodiment of an invention;

FIG. 3 is a block diagram of a realization employed by some embodiments of the invention;

FIG. 4 is a schematic of an unbalance detector according to one embodiment of the invention; and

FIG. 5 is a block diagram of an unbalance detector according another embodiment of the invention.

### DETAILED DESCRIPTION OF THE EMBODIMENTS

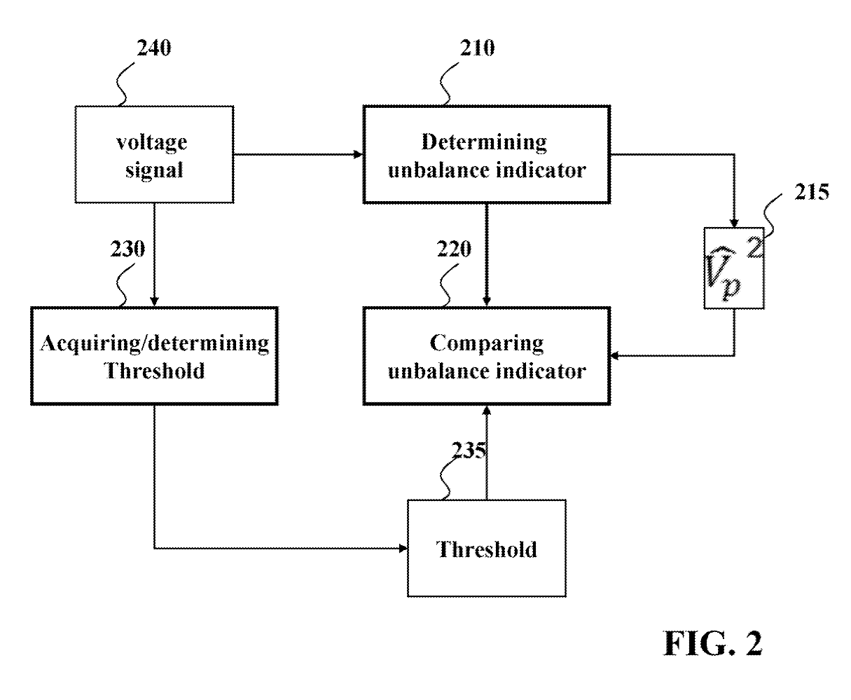

FIG. 2 shows a block diagram of a method for detecting unbalance in a 3-phase voltage signal. The method includes determining 210 an unbalance indicator 215 as a value of a square of amplitude of a positive sequence of the voltage signal and comparing 220 the unbalance indicator 215 with a threshold 235 to determine unbalance of the voltage signal.

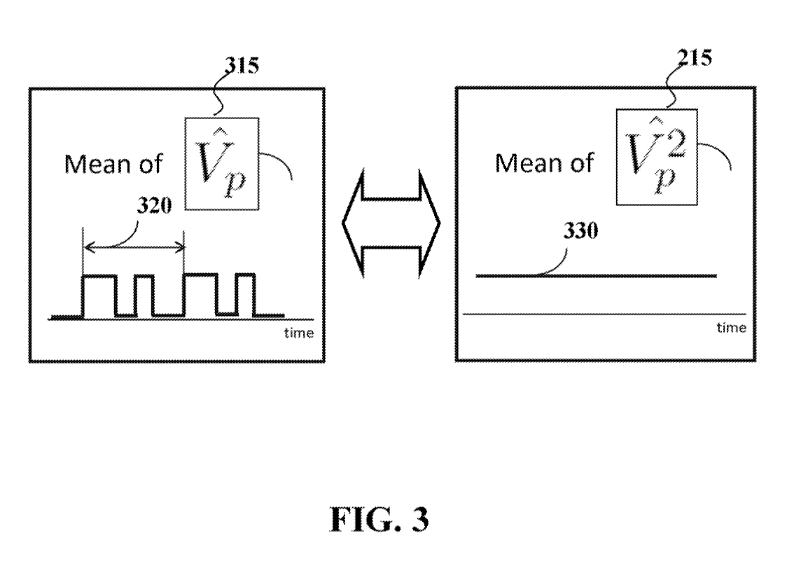

FIG. 3 shows an illustration of a realization employed by some embodiments of the invention. Specifically, it was recognized that the amplitude 315 of positive sequence of the voltage signal is not an optimal indicator for detecting the unbalance of the signal, because a mean 320 of the positive sequence is cyclostationary, i.e., dependent of time. In contrast, the square of the amplitude of positive sequence 215 exhibits different statistical properties. Specifically, a mean 330 of the square of the amplitude of positive sequence is stationary, i.e., independent of time. Accordingly, the threshold selection can be based on that stationary statistical property of the square of the estimate of amplitude of positive sequence and can be used during the entire course of the operation of the power system.

Some embodiments are based on another realization that the threshold can be a function of the signal-to-noise ratio (SNR) of the voltage signal. Referring back to FIG. 2, one embodiment acquires 230 the threshold, wherein the threshold is a function of SNR of the voltage signal. For example, the SNR can be measured at an input terminal of the unbalance detector.

One variation of this embodiment determines 230 the threshold according to γ0.606e^{-0.117SNR(dB)}, wherein γ is a guard coefficient having a value greater than one, and dB is decibel measure, e is an exponential.

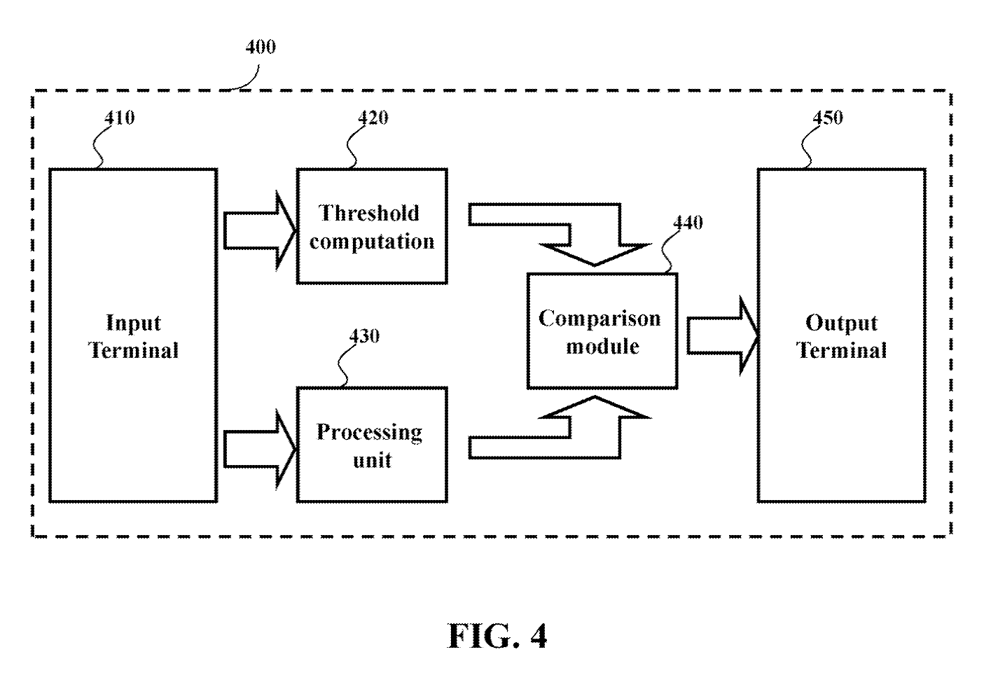

FIG. 4 shows a schematic of an unbalance detector according one embodiment of the invention. The unbalance detector includes an input terminal 410 for acquiring a 3-phase voltage signal. The 3-phase voltage signal can be used for both determining the threshold and the unbalance indicator. For example, the unbalance detector includes a threshold computation module 420 for determining the threshold as a function of signal-to-noise ratio (SNR) of the voltage signal, and a processing unit 430 for determining an unbalance indicator as a value of a square of amplitude of a positive sequence of the voltage signal.

Also, the detector includes a comparison module 440 for comparing the unbalance indicator with the threshold to determine an unbalance of the voltage signal, and an output terminal 450 for signaling the unbalance of the voltage signal. Various modules and units of the unbalance detector can be implemented using a processor. The input terminal can be connected to the power grid. The output terminal can be implemented using any type of signaling mechanism, including signaling with light and/or sound, transmitting messages, and/or trigger an execution of a computer implemented program.

Various embodiments may be implemented using hardware, software or a combination thereof. When implemented in software, the software code can be executed on any suitable processor or collection of processors, whether provided in a single computer or distributed among multiple computers. Such processors may be implemented as integrated circuits, with one or more processors in an integrated circuit component. Though, a processor may be implemented using circuitry in any suitable format.

Further, it should be appreciated that a computer may be embodied in any of a number of forms, such as a rack-mounted computer, a desktop computer, a laptop computer, minicomputer, or a tablet computer. Such computers may be interconnected by one or more networks in any suitable form, including as a local area network or a wide area network, such as an enterprise network or the Internet. Such networks may be based on any suitable technology and may operate according to any suitable protocol and may include wireless networks, wired networks or fiber optic networks.

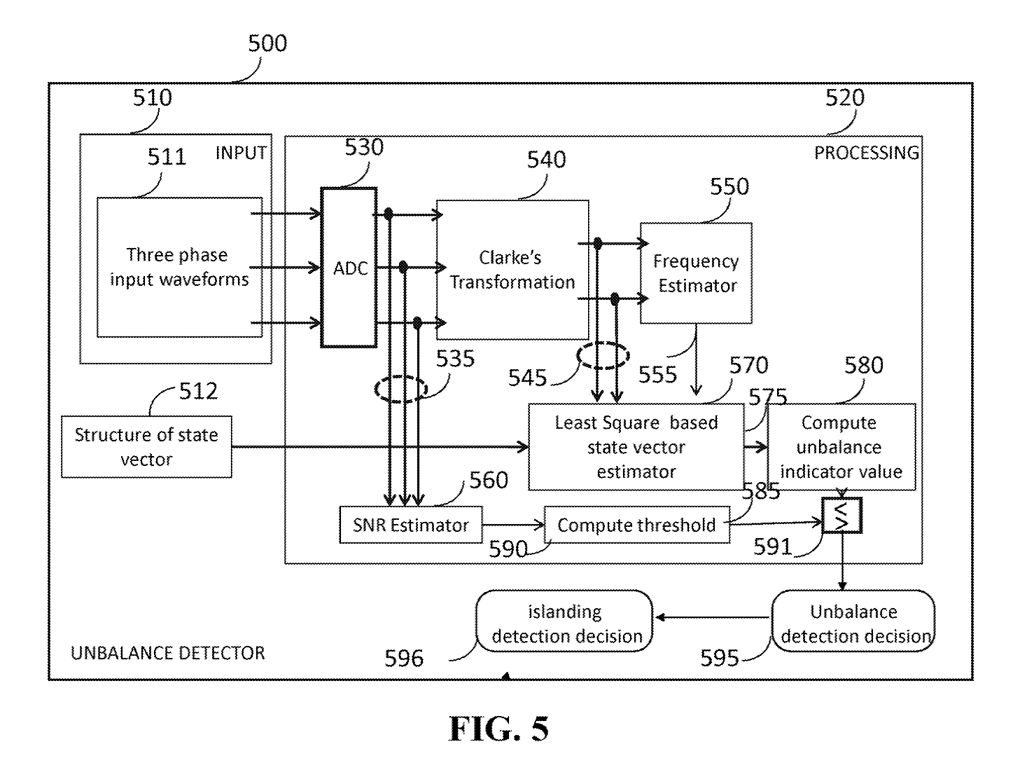

FIG. 5 shows an example of unbalance detector 500 according to one embodiment of the invention. This example serves to illustrate the method for detecting unbalance of the signal, and not intended to limit the scope of the invention. Input 510 to the unbalance detector 500 includes 3-phase voltage signals 511 from the power grid. The discrete 3-phase voltage signals 535 corrupted by additive noise are expressed as

vₐ(n)=Vₐ cos(nw+φₐ)+eₐ(n)

v_{b}(n)=V_{b} cos(nw+φ_{b})+e_{b}(n)

v_{c}(n)=V_{c} cos(nw+φ_{c})+e_{c}(n), (1)

where n is a discrete time index, for i=a, b, c, Vᵢ is the amplitude and φᵢ, is an initial phase angle of the phase i, and w is an angular frequency of the power grid given by w=2πf/fₛ, where f and fₛ are the grid frequency and the sampling frequency, respectively, and e is Gaussian additive noise with zero mean. The additive noise can be caused by the analog-to-digital converter circuit 530 or it may be already present in the signal 511.

The additive noise vector at time instant n is

e(n)=[eₐ(n),e_{b}(n),e_{c}(n)]^{T},

where T is a transpose operator. The noise is assumed to be a zero-mean Gaussian random vector with covariance matrix Q. The noise vectors at different time instants are uncorrelated.

According to Fortescue's theorem, the 3-phase grid voltage signals 535 in vector form can be rewritten as

v(n)=vₚ(n)+vₙ(n)+v₀(n)+e(n),

where vₚ(n), vₙ(n) and v₀(n) represent the positive, negative and zero sequences respectively and defined by

$${v}_{p} ( n ) = {{V}_{p} [ cos {θ}_{p} ( n ) , cos ( {θ}_{p} ( n ) - \frac{2 π}{3} ) , cos ( {θ}_{p} ( n ) + \frac{2 π}{3} ) ]}^{T} \\ {v}_{n} ( n ) = {{V}_{n} [ cos {θ}_{n} ( n ) , cos ( {θ}_{n} ( n ) + \frac{2 π}{3} ) , cos ( {θ}_{n} ( n ) - \frac{2 π}{3} ) ]}^{T} \\ {v}_{0} ( n ) = {{V}_{0} [ cos {θ}_{0} ( n ) , cos {θ}_{0} ( n ) , cos {θ}_{0} ( n ) ]}^{T} , \qquad ( 2 )$$

where Vᵢ and θᵢ(n) for i=p, n, 0 are the amplitude and phase angle of each sequence, respectively.

Clark's Transformation

Some embodiments apply the Clarke transformation 540 to the 3-phase voltage signals 535 described by Equation (1) to determine corresponding αβ-reference frame signals 545 as

[v_{α}(n),v_{β}(n)]^{T}=T[vₐ(n),v_{b}(n),v_{c}(n)]^{T}, (3).

where

$$T = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ]$$

is the Clarke transformation matrix.

The resulting αβ-reference frame signals 545 can be rewritten as

$$[ \begin{matrix}{v}_{α} ( n ) \\ {v}_{β} ( n )\end{matrix} ] = {V}_{p} [ \begin{matrix}cos {θ}_{p} ( n ) \\ sin {θ}_{p} ( n )\end{matrix} ] + {V}_{n} [ \begin{matrix}cos {θ}_{n} ( n ) \\ - sin {θ}_{n} ( n )\end{matrix} ] + [ \begin{matrix}{e}_{α} ( n ) \\ {e}_{β} ( n )\end{matrix} ] . \qquad ( 4 )$$

The covariance of the noise vector at the output of the Clarke's transformation e_{αβ}(n)=[e_{α}(n), e_{β}(n)]^{T} is

Q_{αβ}=TQT^{T}.

The Clarke transformation is beneficial because the zero sequence is canceled, and the number of unknown nuisance parameters is reduced by two. Although the number of unknown parameters in Equation (4) is reduced, Equation (4) is still difficult to solve because the equation includes two sinusoidal signals and is highly non-linear with respect to unknown parameters.

However, based on the fact that θₚ(n) and θₙ(n) have the same frequency, Equation (4) can be rewritten as

$$\begin{matrix}{v}_{α} ( n ) = ( {V}_{p} cos {ϕ}_{p} + {V}_{n} cos {ϕ}_{n} ) cos ( nw ) - \\ ( {V}_{p} sin {ϕ}_{p} + {V}_{n} sin {ϕ}_{n} ) sin ( nw ) + {e}_{α} ( n ) \\ = {V}_{α} cos ( nw + {ϕ}_{α} ) + {e}_{α} ( n )\end{matrix}$$

$$\begin{matrix}{b}_{β} ( n ) = ( {V}_{p} sin {ϕ}_{p} - {V}_{n } sin {ϕ}_{n} ) cos ( nw ) - \\ ( - {V}_{p} cos {ϕ}_{p} + {V}_{n} cos {ϕ}_{n} ) sin ( nw ) + {e}_{β} ( n ) \\ = {V}_{β} cos ( nw + {ϕ}_{β} ) + {e}_{β} ( n )\end{matrix}$$

It can be seen from Equation (5) that each phase in the of αβ domain includes only one noise corrupted sinusoidal signal. The problem becomes estimating parameters of a single-tone sinusoidal signal.

Grid Frequency Estimator

One embodiment includes a frequency estimator 500 to estimate of a grid frequency 555. Any sinusoidal frequency estimators can be used by the detector 500 for estimating the frequency. One embodiment uses unbiased frequency estimator 550 is unbiased. Let w denote the frequency estimate 555.

Least Square Based State Vector Estimator, 270

Given the grid frequency estimate 555, one embodiment estimates the state vector variables using a least square based technique. A s state vector 512 is

$$x = [ \begin{matrix}{V}_{p} cos {ϕ}_{p} + {V}_{n} cos {ϕ}_{n} \\ {V}_{p} sin {ϕ}_{p} - {V}_{n} sin {ϕ}_{n} \\ {V}_{p} sin {ϕ}_{p} + {V}_{n} sin {ϕ}_{n} \\ - {V}_{p} cos {ϕ}_{p} + {V}_{n} cos {ϕ}_{n}\end{matrix} ] \qquad ( 6 )$$

In one embodiment, a least square based estimator 570 is used to estimate x(1), x(2), x(3) and x(4), which are functions of Vₚ, Vₙ, cos φₙ and cos φₙ as shown in Equation (6).

The Equation (5) can be reformulated as a linear equation provided that the frequency w, or an estimation of the frequency is known. Then, the following linear equation can be obtained:

n=g−Hx (7)

where n is defined as

n=[e_{αβ}^{T}(0),e_{αβ}^{T}(1), . . . ,e_{αβ}^{T}(N−1)]^{T} (8)

and the vector g is populated using the observations of the voltage signal according to

g=[v_{α}(0),v_{β}(0),v_{α}(1),v_{β}(1), . . . ,v_{α}(N−1),v_{β}(N−1)]^{T} (9)

and the 2^{nd} and (2n+1)^{th} rows of a frequency matrix H for n=0, 1, . . . , N−1 are

$$[ \begin{matrix}cos ( n {\hat{ω}}_{N - 1} ) & 0 & - sin ( n {\hat{ω}}_{N - 1} ) & 0 \\ 0 & cos ( n {\hat{ω}}_{N - 1} ) & 0 & - sin ( n {\hat{ω}}_{N - 1} )\end{matrix} ] \qquad ( 10 )$$

The noise samples are uncorrelated, and the least square based estimate of the state vector x 275 can be determined according to

\hat{x}=(H^{T}H)⁻¹H^{T}g (11)

Determining Unbalance Indicator

After obtaining the state vector estimate \hat{x} 275, the detector determines the square of the positive sequence voltage, \hat{V}ₚ², as the unbalance indicator.

One embodiment determines the unbalance indicator is computed as follows. Two vectors M₁=[1 0 0 −1] and M₂=[0 −1 −1 0] form a matrix A=[M₁; M₂]. Then, the unbalance indicator \hat{V}ₚ² is determined according to

$${\hat{V}}_{p}^{2} = \frac{1}{4} {\hat{x}}^{T} {A}^{T} A \hat{x} \qquad ( 12 )$$

Alternatively, the unbalance indicator \hat{V}ₚ² can be determined according to

$${\hat{V}}_{p}^{2} = \frac{1}{4} {g}^{T} {C}^{T} Cg \qquad ( 13 )$$

where C=AB and B=(H^{T}H)⁻¹ H^{T}. The alternative representation is advantageous to analyze the biasedness of the estimate. The estimate of unbalance indicator may have some bias, equal to

$$bias = \frac{1}{4} E \{ {n}^{T} {C}^{T} Cn \} .$$

However, we have proved analytically that the expression C^{T}C is independent of the time index, even though C is a function of the frequency estimate and the time index. As an advantage of one embodiment, the bias is not cyclostationary. Otherwise, the compencation for the bias is difficult to implement. This result indicates that the bias decreases with the SNR. Specifically, we have realized that at high SNR levels, e.g., 30 dB or higher, the bias becomes negligable.

Threshold Computation

One embodiment determines 590 the optimum threshold 585 as a function of SNR. The following expression gives the threshold level versus SNR in dB. The SNR is provided by the SNR estimator 560 the threshold is

γ0.606e^{-0.117SNR(dB)}. (14)

We typically set γ to be real number greater than 1.

Unbalance Detection Decision

After the threshold 585 is set and the unbalance indicator \hat{V}ₚ² is computed, an unbalance detection decision is made 595 based on threshold crossing of \hat{V}ₚ² 591. If \hat{V}ₚ² greater than the threshold, then the unbalance is detected. Some embodiments further determine 595 islanding of the power system. For example, if the unbalance is detected, then the islanding is detected as well. In some of those embodiments, the islanding detection triggers an alarm function, which can, e.g., lead to disconnection of distributed generators from the power grid.

Although the invention has been described by way of examples of preferred embodiments, it is to be understood that various other adaptations and modifications can be made within the spirit and scope of the invention. Therefore, it is the object of the appended claims to cover all such variations and modifications as come within the true spirit and scope of the invention.

We claim:

1. A method for detecting unbalance in a 3-phase voltage signal, the method comprising:
determining an unbalance indicator as a value of a square of an amplitude of a positive sequence of the voltage signal; and
comparing the unbalance indicator with a threshold to determine an unbalance of the voltage signal, wherein the steps are performed by a processor.

2. The method of claim 1, further comprising:
acquiring the threshold, wherein the threshold is a function of a signal-to-noise ratio (SNR) of the voltage signal.

3. The method of claim 2, further comprising:
determining the threshold according to
γ0.606e^{0.117SNR(dB)}
wherein γ is a guard coefficient having a value greater than one, and dB is decibel measure, e is an exponential.

4. The method of claim 1, wherein the 3-phase voltage signal is
vₐ(n)=Vₐ cos(nw+φₐ)+eₐ(n)
v_{b}(n)=V_{b} cos(nw+φ_{b})+e_{b}(n)
v_{c}(n)=V_{c} cos(nw+φ_{c})+e_{c}(n),
where n is an instant in time for i=a, b, c, Vᵢ is an amplitude and φᵢ is an initial phase angle of the phase i, and w is an angular frequency of the power grid given by w=2πf/fₛ where f and fₛ are a grid frequency and a sampling frequency, respectively, and e is additive noise, wherein the additive noise vector at time instant n is
e(n)=[eₐ(n),e_{b}(n),e_{c}(n)]^{T},
where T is a transpose operator.

5. The method of claim 4, wherein the 3-phase voltage signal vector is represented by
v(n)=vₚ(n)+vₙ(n)+v₀(n)+e(n),
where vₚ(n), vₙ(n) and v₀(n) represent the positive sequence, a negative sequence, and a zero sequence.

6. The method of claim 5, further comprising:
transforming the 3-phase voltage signal to an αβ-reference frame signals using a Clark transformation matrix; and
determining the unbalance indicator based on the αβ-reference frame signals and an estimation of a frequency of the voltage signal.

7. The method of claim 6, wherein the Clarke transformation matrix is
$$T = \frac{2}{3} [ \begin{matrix}1 & - \frac{1}{2} & - \frac{1}{2} \\ 0 & \frac{\sqrt{3}}{2} & - \frac{\sqrt{3}}{2}\end{matrix} ]$$
and the αβ-reference frame signal is then represented by
$$\begin{matrix}y ( n ) = [ \begin{matrix}{v}_{α} ( n ) \\ {v}_{β} ( n )\end{matrix} ] \\ = {V}_{p} [ \begin{matrix}cos {θ}_{p} ( n ) \\ sin {θ}_{p} ( n )\end{matrix} ] + {V}_{n} [ \begin{matrix}cos {θ}_{n} ( n ) \\ - sin {θ}_{n} ( n )\end{matrix} ] + [ \begin{matrix}{e}_{α} ( n ) \\ {e}_{β} ( n )\end{matrix} ] ,\end{matrix}$$
wherein Vᵢ and θᵢ(n) for i=p, n, 0 are an amplitude and a phase angle of each sequence, respectively.

8. The method of claim 6, further comprising:
determining a state vector estimate \hat{x} of the voltage signal using a least square based estimation based on the αβ-reference frame signals and the frequency of the voltage signal; and
determining the unbalance indicator \hat{V}ₚ² based on the state vector estimate.

9. The method of claim 8, wherein the determining the state vector estimate is according to
\hat{x}=(H^{T}H)⁻¹H^{T}g,
wherein 2nth and (2n+1)th rows of a frequency matrix H, n=0, 1, . . . , N−1, are
$$[ \begin{matrix}cos ( n {\hat{ω}}_{N - 1} ) & 0 & - sin ( n {\hat{ω}}_{N - 1} ) & 0 \\ 0 & cos ( n {\hat{ω}}_{N - 1} ) & 0 & - sin ( n {\hat{ω}}_{N - 1} )\end{matrix} ] ,$$
ŵ is an estimation of a frequency of the voltage signal, and a vector g includes observations of the voltage signal, and T is a transpose operator

10. The method of claim 9, further comprising:
determining the unbalance indicator according to
$${\hat{V}}_{p}^{2} = \frac{1}{4} {\hat{x}}^{T} {A}^{T} A \hat{x} ,$$
wherein a matrix A=[M₁; M₂], a vector M₁=[1 0 0 −1], a vector M₂=[0 −1 −1 0].

11. The method of claim 9, further comprising:
determining the unbalance indicator according to
$${\hat{V}}_{p}^{2} = \frac{1}{4} {g}^{T} {C}^{T} Cg ,$$
wherein a matrix C=AB, a matrix B=(H^{T}H)⁻¹H^{T} a matrix A=[M₁; M₂], a vector M₁=[1 0 0 −1], a vector M₂=[0 −1 −1 0].

12. An unbalance detector, comprising:
an input terminal for acquiring a 3-phase voltage signal;
a threshold computation module for determining a threshold as a function of signal-to-noise ratio (SNR) of the voltage signal;
a processing unit for determining an unbalance indicator as a value of a square of an amplitude of a positive sequence of the voltage signal;
a comparison module for comparing the unbalance indicator with the threshold to determine an unbalance of the voltage signal; and
an output terminal for signaling the unbalance of the voltage signal.

13. The detector of claim 12, wherein the threshold computation module determines the threshold according to
γ0.606e^{0.117SNR(dB)}
wherein γ is a guard coefficient having a value greater than one, and dB is decibel measure, e is an exponential.

14. The detector of claim 12, wherein the processing unit determines the unbalance indicator \hat{V}ₚ² according to
$${\hat{V}}_{p}^{2} = \frac{1}{4} {g}^{T} {C}^{T} Cg ,$$
wherein a matrix C=AB, a matrix B=(H⁷H)⁻¹H^{T} a matrix A=[M₁; M₂], a vector M₁=[1 0 0 −1], a vector M₂=[0 −1 −1 0], and T is a transpose operator, and a vector g includes observations of the voltage signal, a matrix H is a frequency matrix.

15. The detector of claim 12, wherein the processing unit determines the unbalance indicator \hat{V}ₚ² according to
$${\hat{V}}_{p}^{2} = \frac{1}{4} {\hat{x}}^{T} {A}^{T} A \hat{x} ,$$
wherein a matrix A=[M₁; M₂], a vector M₁=[1 0 0 −1], a vector M₂=[0 −1 −1 0], \hat{x} is a state vector estimate, and T is a transpose operator.

16. A method for detecting unbalance in a 3-phase voltage signal, the method comprising:
determining an unbalance indicator as a value of a square of an amplitude of a positive sequence of the voltage signal;
determining a threshold according to γ0.606e^{-0.117SNR(dB)} wherein γ is a guard coefficient having a value greater than one, and dB is decibel measure, e is an exponential; and
comparing the unbalance indicator with the threshold to determine unbalance of the voltage signal, wherein the steps are performed by a processor.

17. The method of claim 16, further comprising:
determining the unbalance indicator \hat{V}ₚ² according to
$${\hat{V}}_{p}^{2} = \frac{1}{4} {g}^{T} {C}^{T} Cg ,$$
wherein a matrix C=AB, a matrix B=(H^{T}H)⁻¹H^{T} a matrix A=[M₁; M₂], a vector M₁=[1 0 0 −1], a vector M₂=[0 −1 −1 0], T is a transpose operator, and a vector g includes observations of the voltage signal, and H is a frequency matrix.

18. The method of claim 16, further comprising:
determining an islanding condition based on the unbalance.
